(19) United States
(12) Patent Application Publication
(10) Pub. No.: US 2023/0144556 A1
(43) Pub. Date: May 11, 2023

(54) FPGA IMPLEMENTATION DEVICE AND METHOD FOR FBLMS ALGORITHM BASED ON BLOCK FLOATING POINT

(71) Applicants: INSTITUTE OF AUTOMATION, CHINESE ACADEMY OF SCIENCES, Beijing (CN); GUANGDONG INSTITUTE OF ARTIFICIAL INTELLIGENCE AND ADVANCED COMPUTING, Guangdong (CN)

(72) Inventors: Lingtian ZHAO, Beijing (CN); Jie HAO, Beijing (CN); Jun LIANG, Beijing (CN); Yafang SONG, Beijing (CN); Lin SHU, Beijing (CN); Sai MA, Beijing (CN); Qiuxiang FAN, Beijing (CN); Hui FENG, Beijing (CN)

(21) Appl. No.: 17/917,643

(22) PCT Filed: May 25, 2020
(86) PCT No.: PCT/CN2020/092035

§ 371 Date: Oct. 7, 2022

(30) Foreign Application Priority Data
Apr. 13, 2020 (CN) 202010286526.6

(51) Int. Cl. G06F 30/34; G06F 17/14; G06F 7/487

(52) U.S. Cl. CPC G06F 30/34; G06F 17/142; G06F 7/4876

(57) ABSTRACT

Disclosed in the present disclosure is an FPGA implementation device and method for an FBLMS algorithm based on block floating point. The method includes: blocking, caching, and reassembling a reference signal, by an input caching and converting module, converting into a block floating point system and performing FFT; filtering, by a filtering module, in a frequency domain and performing dynamic truncation; caching, by an error calculating and output caching module, a target signal on a block basis, converting into a block floating point system, subtracting an output result output from the filtering module from the converted target signal to obtain an error signal, converting the error signal into a fixed point system to obtain a final cancellation result; obtaining, by a weight adjustment amount calculating module and a weight updating and storing module, an adjustment amount of a frequency domain block weight and updating the frequency domain block weight.

### TECHNICAL FIELD

The present disclosure relates to the technical field of real-time adaptive signal processing, in particular to a field programmable gate array (FPGA) implementation device and method for FBLMS algorithm based on block floating point.

### BACKGROUND

Theoretical research and hardware implementation of adaptive filtering algorithm is always research focus in the field of signal processing. When the statistical characteristics of the input signal and noise are unknown or changed, the adaptive filter can automatically adjust its own parameters on the premise of meeting some criteria, to always realize the optimal filtering. Adaptive filter has been widely used in many fields, such as signal detection, digital communication, radar, engineering geophysical exploration, satellite navigation and industrial control. From the perspective of system design, the amount of computation, structure and robustness are the three most important criteria for selecting adaptive filtering algorithm. The least mean square (LMS) algorithm proposed by Widrow and Hoff has many advantages, such as simple structure, stable performance, strong robustness, low computational complexity, and easy hardware implementation, which makes it has stronger practicability.

Frequency domain blocking least mean square (FBLMS) algorithm is an improved form of LMS algorithm. In short, FBLMS algorithm is an LMS algorithm that realizes time domain blocking with frequency domain, and in the FBLMS algorithm, FFT technology can be used to replace time domain linear convolution and linear correlation operation with frequency domain multiplication, which reduces the amount of calculation and is easier to hardware implementation. At present, the hardware implementation of FBLMS algorithm mainly includes three modes: based on CPU platform, based on DSP platform and based on GPU platform, wherein, the implementation mode based on CPU platform is limited by the processing capacity of CPU and is generally used for non-real-time processing; the implementation mode based on DSP platform can meet the requirements only when the real-time performance of the system is not high; and the implementation mode based on GPU platform, based on the ability of powerful parallel computing and floating point operation of GPU, is very suitable for the real-time processing of FBLMS algorithm. However, due to the difficulty and high power consumption of direct interconnection between GPU interface and ADC signal acquisition interface, for the implementation mode based on GPU platform, it is not conducive to the efficient integration of the system and field deployment in outdoor environment.

Field programmable gate array (FPGA) has the capability of large-scale parallel processing and the flexibility of hardware programming. FPGA has abundant internal resource on the computation and a large number of hardware multipliers and adders, and is suitable for real-time signal processing with large amount of calculation and regular algorithm structure. And FPGA has various interfaces, which can be directly connected to various ADC high-speed acquisition interfaces, to have a high integration. FPGA has many advantages, such as low power consumption, fast speed, reliable operation, suitable for field deployment in various environments. FPGA can provide many signal processing IP cores with stable performance, such as FFT, FIR, etc., which makes FPGA easy to develop, maintain and expand functions. Based on the above advantages, FPGA has been widely used in the hardware implementation of various signal processing algorithms. However, FPGA has shortcomings when dealing with high-precision floating point operation, which will consume a lot of hardware resource and even make it difficult to implement complex algorithm.

Generally, when outputting filtering and updating weight vector, FBLMS algorithm needs multiplication operation and has recursive structure, and when the weight vector gradually converges from the initial value to the optimal value, it requires that the data format used in hardware implementation has a large dynamic range and high data accuracy, to minimize the impact of finite word length effect on the performance of the algorithm, and at the same time, in order to facilitate hardware implementation, it is required to be fast and simple, and to occupy less hardware resource on the premise of ensuring the algorithm performance and operation speed. In addition, due to the relatively complex structure of FBLMS algorithm, there is a need to ensure the accurate alignment of the data of each computing node through timing control, which have become urgent problems to be solved when implementing FBLMS algorithm with FPGA.

### SUMMARY

In order to solve the above problem, that is, the problem of conflict between performance, speed and resource when FBLMS algorithm being implemented by a traditional FPGA device in the related art, the present disclosure provides a FPGA implementing device for an FBLMS algorithm based on block floating point. The device includes an input caching and converting module, a filtering module, an error calculating and output caching module, a weight adjustment amount calculating module, and a weight updating and storing module in which:

the input caching and converting module is suitable for blocking, caching and reassembling an input time domain reference signal according to an overlap-save method, converting blocked, cached and reassembled signal from a fixed point system to a block floating point system, and then performing fast Fourier transform (FFT) and caching mantissa, to obtain a frequency domain reference signal with a block floating point system, and outputting the frequency domain reference signal with the block floating point system to the filtering module and the weight adjustment amount calculating module,

the filtering module is suitable for performing complex multiplication operation on the frequency domain reference signal with block floating point system and a frequency domain block weight sent by the weight updating and storing module to obtain a complex multiplication result; determining a significant bit according to a maximum absolute value in the complex multiplication result, and then performing dynamic truncation to obtain a filtered frequency domain reference signal, and sending the filtered frequency domain reference signal to the error calculating and output caching module,

the error calculating and output caching module is configured to perform inverse fast Fourier transform (IFFT) on the filtered frequency domain reference signal; the error calculating and output caching module is further configured to perform ping-pong cache on an input target signal, and convert the cached target signal to a block floating point system; the error calculating and output caching module is further configured to calculate a difference between the target signal converted to the block floating point system and the reference signal on which IFFT is performed to obtain an error signal; and the error calculating and output caching module is further configured to divide the error signal into two same signals, where one of which is sent to the weight adjustment amount calculating module, and the other is converted to fixed point system, and then is subjected to cyclic caching to obtain output continuously cancellation result signals,

the weight adjustment amount calculating module is configured to obtain an adjustment amount of frequency domain block weight with block floating point system based on the error signal and the frequency domain reference signal with block floating point system, and

the weight updating and storing module is configured to convert the adjustment amount of frequency domain block weight with block floating point system to an extended bit width fixed point system, and then update and store it on a block basis; and the weight updating and storing module is further configured to perform dynamic truncation on the updated frequency domain block weight, and then convert a dynamic truncation result to block floating point system, and send the dynamic truncation result with block floating point system to the filtering module.

In some embodiments, the input caching and converting module includes a RAM1, a RAM2, a RAM3, a reassembling module, a converting module 1, an FFT module 1 and a RAM4.

The RAM1, RAM2, RAM3 are configured to divide the input time domain reference signal into data blocks with length of N by means of cyclic caching.

The reassembling module is configured to reassemble the data blocks with the length of N according to the overlap-save method to obtain an input reference signal with a block length of L point(s); where L=N+M−1 and M is an order of a filter.

The converting module 1 is configured to convert the input reference signal with the block length of L point(s) from fixed point system to block floating point system, and send it to the FFT module 1.

The FFT module 1 is configured to perform FFT on the data sent by the converting module 1 to obtain a frequency domain reference signal with block floating point system.

The RAM4 is configured to cache a mantissa of the frequency domain reference signal with block floating point system.

In some embodiments, the blocking, caching and reassemble the input time domain reference signal according to the overlap-save method includes:

step F10, storing K data input in the input time domain reference signal to an end of RAM1 successively; where K=M−1 and M is the order of the filter;

step F20, storing a first batch of N data subsequent to the K data to RAM2 successively;

step F30, storing a second batch of N data subsequent to the first batch of N data to RAM3 successively, and taking the K data at the end of RAM1 and N data in RAM2 as an input reference signal with block length of L point(s), where L=K+N;

step F40, storing a third batch of N data subsequent to the second batch of N data to RAM1 successively, and taking the K data at an end of RAM2 and N data in RAM3 as the input reference signal with block length of L point(s);

step F50, storing a fourth batch of N data subsequent to the third batch of N data to RAM2 successively, and taking the K data at an end of RAM3 and N data in RAM1 as the input reference signal with block length of L point(s); and

step F60, turning to step F30 and repeating step F30 to step F60 until all data in the input time domain reference signal is processed.

In some embodiments, the filtering module includes a complex multiplication module 1, a RAMS and a dynamic truncation module 1.

The complex multiplication module 1 is configured to perform complex multiplication operation on the frequency domain reference signal with block floating point system and the frequency domain block weight sent by the weight updating and storing module to obtain a complex multiplication result.

The RAMS is configured to cache a mantissa of a data on which the complex multiplication operation has been performed.

The dynamic truncation module 1 is suitable for determining a data significant bit according to the maximum absolute value in the complex multiplication result, and then performing dynamic truncation to obtain the filtered frequency domain reference signal.

In some preferred embodiments, the determining the data significant bit according to the maximum absolute value in the complex multiplication result, and then performing dynamic truncation includes:

step G10: obtaining a data of the maximum absolute value in the complex multiplication result;

step G20, detecting from the highest bit of the data of the maximum absolute value, and searching for an earliest bit that is not 0;

step G30, taking the earliest bit that is not 0 is an earliest significant data bit, and a bit immediately subsequent to the earliest significant data bit is a sign bit; and

step G40, truncating a mantissa of data by taking the sign bit as a start position of truncation, and adjusting a block index to obtain the filtered frequency domain reference signal.

In some embodiments, the error calculating and output caching module includes an IFFT module 1, a deleting module, a RAM6, a RAM7, a converting module 2, a difference operation module, a converting module 3, a RAM8, a RAM9 and a RAM10, in which

the IFFT module 1 is configured to perform IFFT on the filtered frequency domain reference signal,

the deleting module is configured to delete a first M−1 data of a data block on which IFFT has been performed to obtain a reference signal with a block length of N point(s) where M is an order of the filter,

the RAM6 and the RAM7 are configured to perform ping-pong cache on the input target signal to obtain a target signal with a block length of N point(s),

the converting module 2 is configured to convert the target signal with the block length of N point(s) to block floating point system on a block basis,

the difference operation module is configured to calculate a difference between the target signal converted to block floating point system and the reference signal with block length of N point(s) to obtain an error signal; and divide the error signal into two same signals and send the two same signals to the weight adjustment amount calculating module and the converting module 3, respectively,

the converting module 3 is configured to convert the error signal to fixed point system, and

the RAM8, RAM9 and RAM10 are configured to convert the error signal with fixed point system to output continuously cancellation result signals by means of cyclic caching.

In some embodiments, the weight adjustment amount calculating module includes a conjugate module, a zero inserting module, an FFT module 2, a complex multiplication module 2, a RAM11, a dynamic truncation module 2, an IFFT module 2, a zero setting module, an FFT module 3 and a product module, in which

the conjugate module is configured to perform conjugate operation on the frequency domain reference signal with block floating point system output from the input caching and converting module,

the zero inserting module is configured to insert M−1 zeros at the front end of the error signal where M is an order of the filter,

the FFT converting module 2 is configured to perform FFT on the error signal into which zeroes are inserted,

the complex multiplication module 2 is configured to perform complex multiplication on the data on which the conjugate operation is performed and the data on which FFT is performed to obtain a complex multiplication result,

the RAM11 is configured to cache a mantissa of the complex multiplication result,

the dynamic truncation module 2 is configured to determine a data significant bit according to the maximum absolute value in the complex multiplication result of the complex multiplication module 2, and then perform dynamic truncation to obtain an update amount of the frequency domain block weight,

the IFFT module 2 is configured to perform IFFT on the update amount of the frequency domain block weight,

the zero setting module is configured to set a L-M data point(s) at a rear end of the data block on which IFFT is performed by the IFFT module 2 to 0,

the FFT module 3 is configured to preform FFT on the data output from the zero setting module, and

the product module is configured to perform product operation on the data on which FFT is performed by the FFT module 3 and a set step factor to obtain an adjustment amount of the frequency domain block weight with block floating point system.

In some embodiments, the weight updating and storing module includes a converting module 4, a summing operation module, a RAM12, a dynamic truncation module 3 and a converting module 5, in which:

the converting module 4 is configured to convert the adjustment amount of the frequency domain block weight with block floating point system output from the weight adjustment amount calculating module to the extended bit width fixed point system,

the summing operation module is configured to sum the adjustment amount of the frequency domain block weight with extended bit width fixed point system and a stored original frequency domain block weight, to obtain an updated frequency domain block weight,

the RAM12 is configured to cache the updated frequency domain block weight,

the dynamic truncation module 3 is configured to determine a data significant bit according to the maximum absolute value in the cached updated frequency domain block weight, and then perform dynamic truncation, and

the converting module 5 is configured to convert the data output from the dynamic truncation module 3 to block floating point system, to obtain a frequency domain block weight required by the filtering module.

According to another aspect of the present disclosure, provided is an FPGA implementation method for FBLMS algorithm based on block floating point, which is preformed by the above FPGA implementation device for FBLMS algorithm based on block floating point, the method includes:

step S10, blocking, caching and reassembling an input time domain reference signal x(n) according to an overlap-save method, converting blocked, cached and reassembled signal from a fixed point system to a block floating point system and performing fast Fourier transform (FFT) to obtain X(k);

step S20, multiplying X(k) by a current frequency domain block weight W(k) to a multiplication result, determining a significant bit according to a maximum absolute value in the multiplication result, and then performing dynamic truncation to obtain a filtered frequency domain reference signal Y(k);

step S30, performing inverse fast Fourier transform (IFFT) on Y(k) and discarding points to obtain a time domain filter output y(k), caching a target signal d(n) on a block basis and converting the cached target signal d(n) to block floating point system to obtain d(k), and subtracting y(k) from d(k) to obtain an error signal e(k);

step S40, converting the error signal e(k) to fixed point system, then caching and outputting to obtain output continuously final cancellation result signals e(n).

In some embodiments, the frequency domain block weight W(k) is adjusted, calculated and updated synchronously with the error signal e(k) and X(k) by the following steps:

step X10, inserting zero block in e(k) and then performing FFT to obtain the frequency domain error E(k);

step X20, calculating a conjugation of X(k) and multiplying by E(k), and then multiplying by a set step factor ,u to obtain an adjustment ΔW(k) of a frequency domain block weight;

step X30, converting ΔW(k) to extended bit width fixed point system and summing it with the current frequency domain block weight W(k) to obtain an updated frequency domain block weight W(k+1); and

step X40, determining a significant bit of the updated frequency domain block weight W(k+1) when the updated frequency domain block weight W(k+1) is stored, and performing a dynamic truncation on the updated frequency domain block weight W(k+1) when being output and converting it to block floating point system to be used as a frequency domain block weight for a next stage.

The beneficial effects of the present disclosure are as follows.

(1) In the FPGA implementation device and method for FBLMS algorithm based on block floating point provided by the present disclosure, the block floating point data format is used in the process of filtering and weight adjustment calculation for the recursive structure of the FBLMS algorithm to ensure that the data has a large dynamic range. The dynamic truncation is performed according to the actual size of the current data block, which avoids the loss of data significant bit and improves the data accuracy. The extended bit width fixed point data format is used when the weight is updated and stored, and there is no truncation in the calculation process, which ensures the precision of the weight coefficient. By adopting block floating point and fixed point data formats in different computing nodes, the influence of finite word-length effect is effectively reduced, and the hardware resource is saved while ensuring the algorithm performance and operation speed.

(2) In the present disclosure, the synchronous control method of valid flags is used in the process of data calculation and caching and thus complex timing control is realized and the accurate alignment of the data of each computing node is ensured.

(3) In the present disclosure, modular design method is used to decompose the complex algorithm flow into five functional modules, which improves the reusability and scalability. The multi-channel adaptive filtering function can be realized by instantiating multiple embodiments, and the processable data bandwidth can be increased by increasing the working clock rate.

### BRIEF DESCRIPTION OF THE DRΔWINGS

Other features, objectives and advantages of the present disclosure will be more apparent by reading the detailed description of the non-limiting embodiments made with reference to the following drawings.

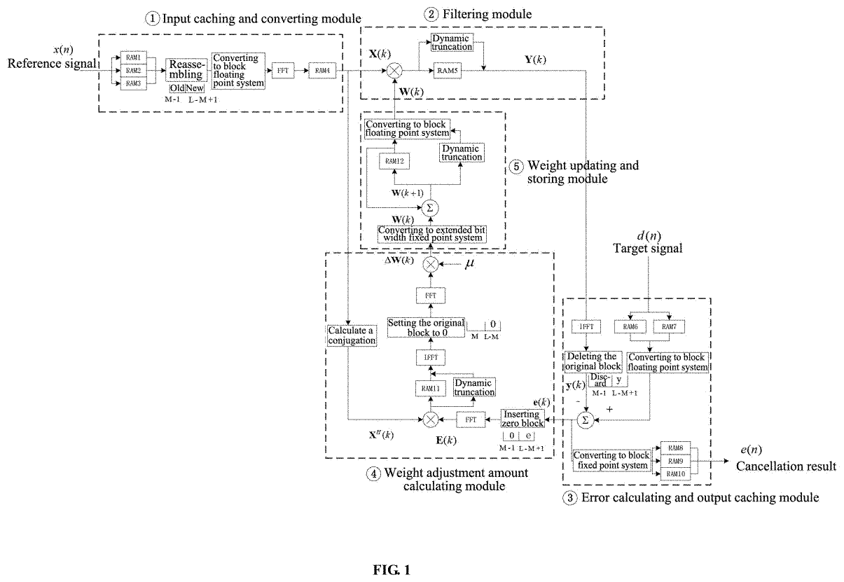

FIG. 1 is a frame diagram of an FPGA implementation device for FBLMS algorithm based on block floating point according to the present disclosure;

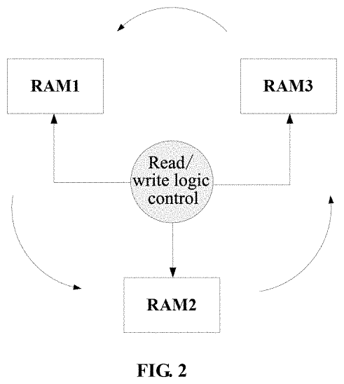

FIG. 2 is a schematic diagram of data overlap-save cyclic storage of an input caching and converting module in an embodiment of an FPGA implementation device for FBLMS algorithm based on block floating point according to the present disclosure;

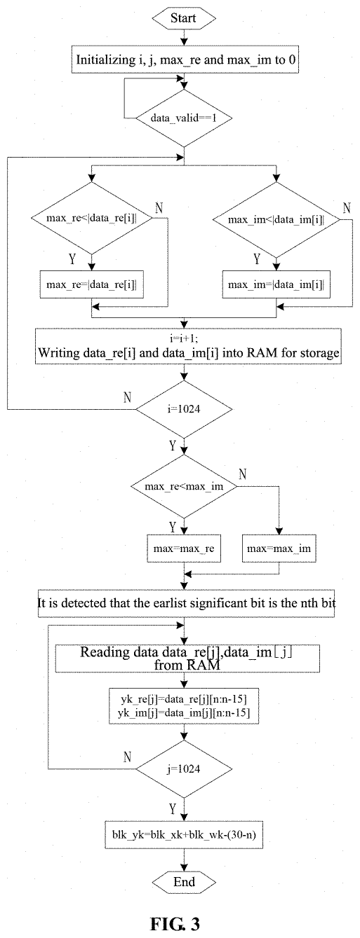

FIG. 3 is a flow schematic diagram of data dynamic truncation of a filtering module in an embodiment of an FPGA implementation device for FBLMS algorithm based on block floating point according to the present disclosure;

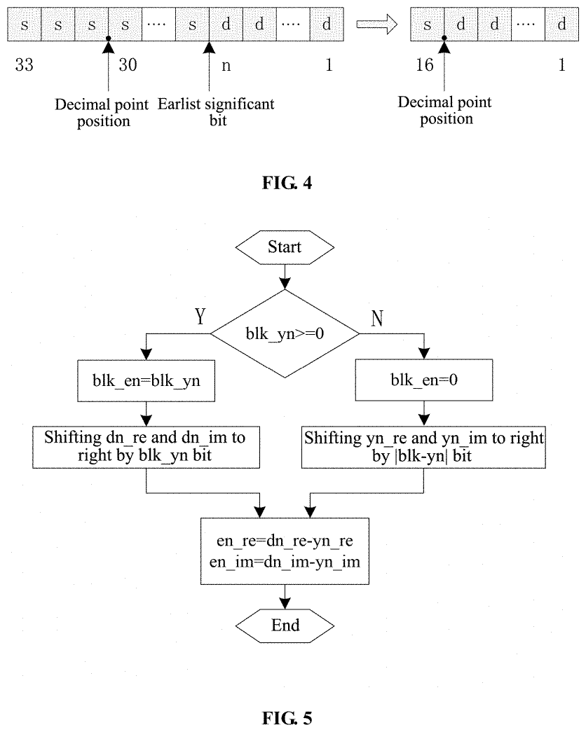

FIG. 4 is a schematic diagram of decimal point shifting process in a dynamic truncation process in an embodiment of an FPGA implementation device for FBLMS algorithm based on block floating point according to the present disclosure;

FIG. 5 is a flow schematic diagram of subtracting operation of an error calculating and output caching module in an embodiment of an FPGA implementation device for FBLMS algorithm based on block floating point according to the present disclosure; and

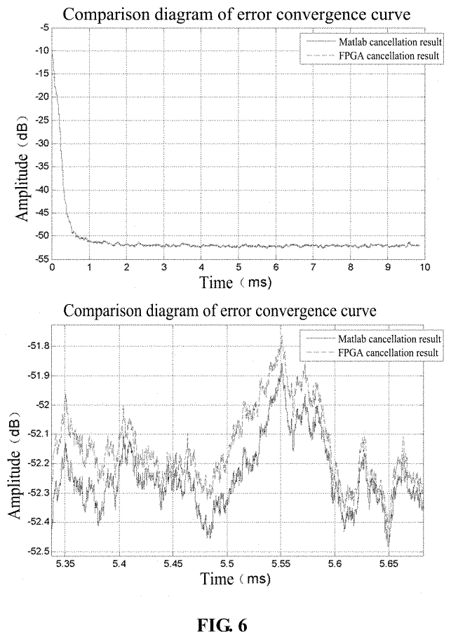

FIG. 6 is a comparison diagram of an error convergence curve of clutter cancellation application in an embodiment of an FPGA implementation device for FBLMS algorithm based on block floating point according to the present disclosure.

### DETAILED DESCRIPTION

The present application will be further described in detail below in conjunction with the accompanying drawings and embodiments. It can be understood that the specific embodiments described herein are only used to explain the relevant disclosure, not to limit this disclosure. In addition, it should be noted that for ease of description, only parts related to the relevant disclosure are shown in the drawings.

It should be noted that the embodiments in the present disclosure and the features in the embodiments can be combined with each other without conflict. The present disclosure will be described in detail below with reference to the accompanying drawings and in conjunction with embodiments.

An FPGA implementation device for FBLMS algorithm based on block floating point according to the present disclosure, includes an input caching and converting module, a filtering module, an error calculating and output caching module, a weight adjustment amount calculating module and a weight updating and storing module, in which

the input caching and converting module is suitable for blocking, caching and reassembling an input time domain reference signal according to an overlap-save method, converting blocked, cached and reassembled signal from a fixed point system to a block floating point system, and then performing fast Fourier transform (FFT) and cache mantissa, to obtain a frequency domain reference signal with a block floating point system, and outputting the frequency domain reference signal with the block floating point system to the filtering module and the weight adjustment amount calculating module,

the filtering module is suitable for performing complex multiplication operation on the frequency domain reference signal with block floating point system and a frequency domain block weight sent by the weight updating and storing module to obtain a complex multiplication result; and determining a significant bit according to a maximum absolute value in the complex multiplication result, and then perform dynamic truncation to obtain a filtered frequency domain reference signal, and sending the filtered frequency domain reference signal to the error calculating and output caching module,

the error calculating and output caching module is configured to perform inverse fast Fourier transform (IFFT) on the filtered frequency domain reference signal; the error calculating and output caching module is further configured to perform ping-pong cache on an input target signal, and convert the cached target signal to a block floating point system; the error calculating and output caching module is further configured to calculate a difference between the target signal converted to the block floating point system and the reference signal on which IFFT is performed, to obtain an error signal; and the error calculating and output caching module is further configured to divide the error signal into two same signals, where one of which is sent to the weight adjustment amount calculating module, and the other is converted to fixed point system, and then is subjected to cyclic caching to obtain output continuously cancellation result signals,

the weight adjustment amount calculating module is configured to obtain an adjustment amount of frequency domain block weight with block floating point system based on the error signal and the frequency domain reference signal with block floating point system, and

the weight updating and storing module is configured to convert the adjustment amount of frequency domain block weight with block floating point system to an extended bit width fixed point system, and then update and store it by block; and the weight updating and storing module is also configured to perform dynamic truncation on the updated frequency domain block weight, and then convert a dynamic truncation result to block floating point system, and send the dynamic truncation result with block floating point system to the filtering module.

In order to more clearly describe the FPGA implementation device for FBLMS algorithm based on block floating point according to the present disclosure, the modules in the embodiment(s) of this disclosure are described in detail below in conjunction with FIG. 1.

An FPGA implementation device for FBLMS algorithm based on block floating point according to an embodiment of the present disclosure includes input caching and converting module, filtering module, error calculating and output caching module, weight adjustment amount calculating module and weight updating and storing module. Each module is described in detail as follows.

The connection relationship between each module is as follows: the input caching and converting module is connected to the filtering module and the weight adjustment amount calculating module, respectively; the filtering module is connected to the error calculating and output caching module, the error calculating and output caching module is connected to the weight adjustment amount calculating module, the weight adjustment amount calculating module is connected to the weight updating and storing module, and the weight updating and storing module is connected to the filtering module.

The input caching and converting module is suitable for blocking, caching and reassembling the input time domain reference signal x(n) according to the overlap-save method, converting the blocked, cached and reassembled signal from fixed point system to block floating point system, and then performing FFT and caching mantissa. The definitions of interfaces in this module are shown in table 1:

TABLE 1

| Definition of | | Bit | |
|---|---|---|---|
| Interface | I/O | width | Illustration |
| clk_L | I | 1 | Low-speed write clock when data |
| | | | are input to caches |
| clk_H | I | 1 | High-speed read clock when data |
| | | | are input to caches |
| xn_re | I | 16 | Real part of input reference signal |
| xn_im | I | 16 | Imaginary part of input reference signal |
| write_en_flag | I | 1 | Flag for target signal cache starts to write |
| read_en_flag | I | 1 | Flag for target signal cache starts to read |
| ek_flag | I | 1 | Flag for the weight adjustment |
| | | | amount calculating module reads data |
| | | | from cache of this module |
| xk_re | O | 16 | Real part of output data |
| xk_im | O | 16 | Imaginary part of output data |
| blk_xk | O | 6 | Block index of output data |
| xk_valid_ | O | 1 | Flag for indicating that the data entering |
| filter | | | the filtering module is valid |
| xk_valid_ | O | 1 | Flag for indicating that the data |
| weight | | | entering the weight adjustment amount |
| | | | calculating module is valid |
| re_weight | O | 1 | Flag for informing the weight |
| | | | updating and storing |
| | | | module to start reading of weight |

The input time domain reference signal x(n) has two parts of real part xn re and imaginary part xn im, and both real part and imaginary part have the bit widths of 16 bits. In FBLMS algorithm, adaptive filtering operation is realized in frequency domain using FFT. Data need to be segmented since the processing of FFT is performed according to a set number of points. However, after the input data is segmented by the frequency domain method, there is a distortion when the processing results are spliced. In order to solve this problem, an overlap-save method is used in the present disclosure. The input time domain reference signal is x(n), and the order of the filter is M, x(n) is segmented into segments with the same length, the length of each segment is recorded as L, and L is required to be the power of 2 for conveniently performing FFT/IFFT. There are K overlapping points between adjacent segments, and for the overlap-save method, the larger the K, the greater the calculation amount. It is preferable that the number of overlapping points is equal to the order of the filter minus 1, that is, K=M−1. The length of each new data block is N points, and N=L-M+1.

As shown in FIG. 2, it is a schematic diagram of data overlap-save cyclic storage of the input caching and converting module in an embodiment of the FPGA implementation device for FBLMS algorithm based on block floating point according to the present disclosure. The process of blocking, caching and reassembling the input time domain reference signal according to the overlap-save method includes:

Step F10, storing K data in the input time domain reference signal to an end of RAM1 successively; where K=M−1 and M is the order of filter;

Step F20, storing the first batch of N data subsequent to the K data to RAM2 successively;

Step F30, storing the second batch of N data subsequent to the first batch of N data to RAM3 successively, and taking the K data at the end of RAM1 and N data in RAM2 as an input reference signal with block length of L point(s), where L=K+N;

Step F40, storing the third batch of N data subsequent to the second batch of N data to RAM1 successively, and taking the K data at the end of RAM2 and N data in RAM3 as the input reference signal with block length of L point(s);

Step F50, storing the fourth batch of N data subsequent to the third batch of N data to RAM2 successively, and taking the K data at the end of RAM3 and N data in RAM1 as the input reference signal with block length of L point(s);

Step F60, turning to step F30 and repeating step F30 to step F60 until all data in the input time domain reference signal is processed.

Each RAM is configured to a simple dual ports mode, and has a depth of N. In the corresponding implementation process, there are a write control module and a read control module, and the corresponding functions are completed by a state machine. The write clock is a low-speed clock clk L, the read clock is a high-speed processing clock clk H. The two flag signals write en flag, read en flag are generated in read control and write control processes, and the two flag signals are sent to the error calculating and output caching module to control the process of caching and reading the target signal and to ensure that the reference signal and the target signal are aligned in time.

Due to the high performance of XILINX's latest FFT core, FFT core is used to perform FFT to simplify programming difficulty and improve efficiency. Considering the compromise between operation time and hardware resource, the implementation structure of Radix-4 and Burst I/O is adopted, and the block floating point method is used to represent the results of data processing, which improves the dynamic range. The data entering the FFT core is complex and the real part of that is xn re, the imaginary part of that is xn_im, the bit width is 16 bits, the highest bit is the sign bit, and the other bits are the data bit. The decimal point is set between the sign bit and the first data bit, that is, the real part and imaginary part of the input data are pure decimals with an absolute value less than 1. The data of every L point(s) is a segment, which is transformed by FFT core. Since the data format of the result is set as block floating point, the processing result of FFT core has two parts of block index and mantissa data. Block index blk_xk is a signed number of 6 bits, and the format of mantissa data is the same as that of input data.

The data on which FFT is performed needs to be cached since it will be used twice successively, where it is sent to the filtering module for convolution operation with the weight of frequency domain block for the first time, and it is sent to the weight adjustment amount calculating module for performing correlation operation with the error signal for the second time. For the mantissa data, it is stored in a simple dual ports RAM with a depth of L, and for the block index, it can be registered with a register as a block of data with L point(s) has the same block index. The cache of mantissa data is also divided into two control modules: a write control module and a read control module. In the process of write control, when valid flag data_valid in the FFT result is valid, the write control process enters write state, and returns to the initial state after L data is written. Once the write state is completed, the read control process enters the read state from the initial state and makes the flag xk_valid_filter valid, and the data and valid flag are sent to the filtering module; meanwhile, by making the flag re_weight valid, the weight updating and storing module is informed to start reading the weight and sending it to the filtering module. When flag ek_flag is valid, entering the read state again and making flag xk_valid_weight valid, the data and valid flag are sent to the weight adjustment amount calculating module.

The filtering module provides the filtering function by frequency domain complex multiplication instead of time domain convolution, and determines the significant bit according to the maximum absolute value in the complex multiplication result, and then performs dynamic truncation. The definitions of interfaces in this module are shown in table 2.

TABLE 2

| Definition | | Bit | |
|---|---|---|---|
| of Interfaces | I/O | width | Illustration |
| xk_re | I | 16 | Real part of frequency domain reference |
| | | | signal |
| xk_im | I | 16 | Imaginary part of frequency domain |
| | | | reference signal |
| xk_valid_ | I | 1 | Data valid flag for frequency domain |
| filter | | | reference signal |
| blk_xk | I | 1 | Block index of frequency domain |
| | | | reference signal |
| wk_re | I | 16 | Real part of frequency domain |
| | | | weight coefficient |
| wk_im | I | 16 | Imaginary part of frequency domain weight |
| | | | coefficient |
| wk_valid | I | 1 | Valid flags for frequency domain |
| | | | weight coefficient |
| blk_wk | I | 6 | Block index of frequency domain |
| | | | weight coefficient |
| yk_re | O | 16 | Real part of filtered and truncated data |
| yk_im | O | 16 | Imaginary part of filtered and truncated data |
| yk_valid | O | 1 | Valid flag of filtered and truncated data |
| blk_yk | O | 6 | Block index of filtered and truncated data |

The core of the filtering process is a complex multiplier, which is used for the complex multiplication of frequency domain reference signal and frequency domain weight coefficient. It should be noted that the two data used for complex multiplication both have block floating point format, and complex multiplication results also have block floating point format. According to the algorithm, the block index of the result is a sum of the block index blk_xk and blk_wk of the two data, and the mantissa of the result is a complex product of the mantissas of the two data. The complex multiplication operation of the mantissas of the two data can be performed by XILINX's complex multiplication core. A hardware multiplier is selected, and there is a delay of 4 clock cycles. Before complex multiplication, the two data need to be aligned according to the data valid flag xk_valid_filter and wk_valid. The bit widths of the real part and imaginary part of the two complex data are 16 bits, and the bit width of the complex product is extended to 33 bits.

Due to the closed-loop structure of FBLMS algorithm, the product result must be truncated, otherwise its bit width will continue to be extended until the FBLMS algorithm cannot be realized. There are many ways to truncate 16 bits from a result of 33 bits. In the process of truncation, it should not only ensure that no overflow occurs, but also consider making full use of the significant bit of the data, thereby improving the accuracy of the data. Therefore, 16 bits cannot be invariably truncated from a certain bit, but the truncation position should be changed according to the actual size of the data. Assuming that the multiplication result data valid flag is data_valid, the real part of the complex multiplication result data is data_re, and the imaginary part is data_im, as shown in FIG. 3, it is the flow schematic diagram of data dynamic truncation of the filtering module in an embodiment of the FPGA implementation device for FBLMS algorithm based on block floating point according to the present disclosure, which includes:

Step G10: in order to find out the maximum absolute value of the L data in the block complex multiplication result, storing the complex multiplication result data to RAM for temporary storage while comparing, where the depth of RAM is L and the bit width of the RAM is 33 bits and obtaining the maximum absolute value after storing the L data;

Step G20, detecting from the highest bit of the data of the maximum absolute value, and searching out an earliest bit that is not 0;

Step G30, assuming that the nth bit with respect to the lowest bit of the maximum absolute value is not 0, regarding the nth bit as the earliest significant data bit, and the n+1 bit as the sign bit, that is, the position where data truncation starts;

Step G40, reading out the L data one by one from RAM, and truncating 16 bits from n+1th bit, such that no overflow occurs and the significant bit of the data is fully used.

The format of the data after truncation is the same as before, for example, the highest bit is the sign bit, and the decimal point is located between the sign bit and the first data bit, and it can be seen that the decimal point has shifted during truncation. In order to make the actual size of the data remains unchanged, the size of the block index needs to be adjusted accordingly. As shown in FIG. 4, it is a schematic diagram of decimal point shifting process in the process of dynamic truncation in an embodiment of the FPGA implementation device for FBLMS algorithm based on block floating point according to the present disclosure. The bit widths of the two data for complex multiplication are 16 bits, where 1 bit is sign bit and 15 bits are decimal bits. Therefore, the complex product will have 30 bits of decimal bit, and the decimal point is at the 30th bit. After truncation, it is equivalent to shifting the decimal point to the right to the nth bit, a total of (30−n) bits are shifted to the right, and the data is enlarged by 2³⁰⁻ⁿ times. Therefore, the block index should be subtracted by (30−n). For example, the block index of the final output data Y(K) is shown in formula (1).

blk_yk=blk_xk+blk_wk−(30−n) Formula (1)

Where blk_yk represents a block index of filtered output data, blk_xk represents a block index of the frequency domain reference signal, blk_wk represents a block index of the frequency domain weight coefficient, (30−n) represents the number of bit the decimal have shifted to the right after truncation.

The error calculating and output caching module is configured to block and cache the target signal d(n) and convert the blocked and cached target signal to block floating point system, subtract the filtered output signal from the blocked and cached target signal with block floating point to obtain the error signal, convert the error signal to fixed point system, cache and output to obtain output continuously final cancellation result signals e(n). The definitions of interfaces in this module are shown in table 3.

TABLE 3

| Interface | | Bit | |
|---|---|---|---|
| definition | I/O | width | Illustrate |
| yk_re | I | 16 | Real part of filtered output data |
| yk_im | I | 16 | Imaginary part of filtered output data |
| yk_valid | I | 1 | Valid flag for filtered output data |
| blk_yk | I | 6 | Block index of filtered output data |
| dn_re | I | 16 | Real part of input target signal |
| dn_im | I | 16 | Imaginary part of input target signal |
| write_en_flag | I | 1 | Flag for target signal cache starts to write |
| read_en_flag | I | 1 | Flag for target signal cache starts to read |
| en_re | O | 16 | Real part of cancellation result data |
| en_im | O | 16 | Imaginary part of cancellation result data |
| en_valid | O | 1 | Valid flag for cancellation result data |
| ek_re | O | 16 | Real part of error signal |
| ek_im | O | 16 | Imaginary part of error signal |
| ek_valid | O | 1 | Valid flag for error signal |
| blk_ek | O | 6 | Block index of error signal |

The output Y(K) of the filtering module is frequency domain data, which needs to be changed back to time domain before cancellation. By controlling FWD_INV port of FFT core, IFFT operation can be easily performed. The formula used by XILINX's FFT core in performed IFFT operation is shown in Formula (2).

$$x ( n ) = {\sum }_{k = 0}^{L - 1} X ( k ) {e}^{j n k 2 π / L} n = 0 , … , L - 1 \qquad Formula ( 2 )$$

Compared with the actual IFFT operation formula, the formula (2) lacks a product factor 1/L, so the IFFT result is magnified by L times and needs to be corrected. The IFFT result is also in a form of block floating point, and the block index of the IFFT result is subtracted by log₂L, that is the IFFT result is reduced by L times and the correction function can be realized.

The filtered output data is in block floating point form, and the block index is blk_yk. Mantissa part of the filtered output data is sent to the FFT core for performing IFFT transformation, and assuming that the block index output by the FFT core is blk_tmp, mantissa is yn_re and yn_im, then the final block index blk_yn of the IFFT result is as shown in formula (3).

blk_yn=blk_yk+blk_tmp−log₂L Formula (3)

Where blk_yk represents the block index of the filtered truncated data.

Because the overlap-save method is used, the front M−1 point(s) shall be rounded off for the data on which IFFT is performed, and the remaining N point(s) of data is the time domain filtering result.

The ping-pong caching is performed on the target signal d(n), and writing is performed in the low-speed clock clk_L, and reading out is performed in high speed clock clk_H, and the read/write control flags write_en_flag and read_en_flag are used to align the target signal d(n) with the input reference signal x(n).

As shown in FIG. 5, it is a flow schematic diagram of difference operation of the error calculating and output caching module in an embodiment of the FPGA implementation device the FBLMS algorithm based on block floating point according to the present disclosure. The filtering result signal is block floating point data, and the target signal can be regarded as block floating point data with block index of zero. Order matching must be performed on the filtering result signal and the target signal before performing a difference operation. Order matching is performed according to the principle of small order to large order. If the block index of the filtering result is greater than the block index of the target signal, the target signal would be shifted to the right, otherwise, the filtering result would be shifted to the right. After the order matching is performed, a difference operation is performed on the mantissas of the two data according to the fixed point number.

The difference result data is divided into two ways, where one way is sent to the weight adjustment amount calculating module for performing correlation operation on the reference signal, and the other way is subjected to format transformation and output caching to obtain the final cancellation result data.

The subtracted data is still in block floating point form. Before outputting caching is performed, the subtracted data needs to be converted to fixed point form, that is, the block index is removed. Block index blk en so the data needs to be shifted to left by blk en bit(s). Moving to left will not cause data overflow since the subtracted data values are very small.

Similar to the input caching, output caching is performed using three simple dual ports RAMs, and processes of converting high-speed data to low-speed data, and realizing continuously data output include:

Step 1: start caching, storing the first batch of N data to RAM8 successively;

Step 2: storing the second batch of N data to RAM9 successively, and meanwhile reading the N data in RAM8 and outputting it as the cancellation result;

Step 3: storing the third batch of N data to RAM10 successively, and meanwhile reading the N data in RAM8 and outputting it as the cancellation result;

Step 4: storing the fourth batch of N data to RAM8 successively, and meanwhile reading the N data in RAM10 and outputting it as the cancellation result;

Step 5, turning to step 2 and repeating step 2 to step 5 until all the data is output.

In the output caching of the module, it must ensure that the low-speed clock has read out all the previous segment of data when the next segment of data arrives, thereby ensuring no data loss. Because the time interval between the two segments of data is exactly the time required for the low-speed clock CLK_L to write the N point(s) of data, the N point(s) of data is just read out at the same clock frequency, and the data can be read continuously.

The weight of frequency domain block is updated through the weight adjustment amount calculating module and the weight updating and storing module. The weight adjustment amount calculating module is configured to perform relevant operation by frequency domain multiplication to obtain the weight adjustment of frequency domain block. The definitions of interfaces in this module are shown in table 4.

TABLE 4

| Definitions | | Bit | |
|---|---|---|---|
| of Interfaces | I/O | width | Illustration |
| xk_re | I | 16 | Real part of frequency domain |
| | | | reference signal |
| xk_im | I | 16 | Imaginary part of frequency domain |
| | | | reference signal |
| blk_xk | I | 6 | Block index of frequency domain |
| | | | reference signal |
| xk_valid_ | I | 1 | Valid flag of frequency domain |
| weight | | | reference signal |
| ek_re | I | 16 | Real part of error signal |
| ek_im | I | 16 | Imaginary part of error signal |
| ek_valid | I | 1 | Valid flag of error signal |
| blk_ek | I | 6 | Block index of error signal |
| mu | I | 16 | Step factor |
| ek_flag | O | 1 | Flag for reading data when sending to the |
| | | | input caching and converting module |
| det_wk_re | O | 32 | Real part of weight adjustment |
| det_wk_im | O | 32 | Imaginary part of weight adjustment |
| det_wk_valid | O | 1 | Valid flag of weight adjustment |
| blk_det_wk | O | 6 | Block index of weight adjustment |

The output e(k) of the error signal is a time domain signal of N point(s), M−1 zero value is inserted at a front end of the time domain signal, and then the FFT transformation of L point is performed to obtain the frequency domain error signal E(k). The method of inserting the zero block is as follows: sending the zero value to the FFT core at the M−1 th clock before the error signal is valid; and then sending the error signal of L-M+1 point to the FFT core when the error signal is just valid after M−1 zero value is sent. In this way, the error signal does not need to be cached, and the processing time is saved.

The data valid flag ek_flag for E(k) is sent to the input caching and converting module. When data valid flag ek_flag is valid, the frequency domain reference signal X(k) is read out from RAM4 and a conjugation process in which the real part remains unchanged and the imaginary part is reversed is preformed, the data E(k) is aligned with X^{H}(k) according to two valid flags ek_flag and xk_valid weight, and then complex multiplication is performed on data E(k) and X^{H}(k) The number of bits of data on which complex multiplication is performed expands, and dynamic truncation is required. The specific process of the dynamic truncation is the same as that of the filtering module.

The truncated data is first subjected to IFFT operation to be changed back to the time domain to obtain a relevant operation result, the last L-M points of the relevant operation result is discarded to obtain the time domain product of M points, L-M zero values are added at its end, and then the FFT transformation of L points is performed to obtain a frequency domain data. The frequency domain data is still in block floating point form, and the bit widths of the real part and imaginary part of the mantissa data are 16 bits., step factor ,u is expressed by a pure decimal with a bit width of 16 bits and in fixed point form since it is constant in each cancellation process and its value is usually very small. The frequency domain data and the step factor ,u are multiplied to obtain an adjustment ΔW(k) of the frequency domain block weight. The bit width of its mantissa data is extended to 32 bits. The adjustment ΔW(k) of the frequency domain block weight does not need to be truncated and is directly sent to the subsequent processing module.

The weight updating and storing module is configured to convert the adjustment of the frequency domain block weight to extended bit width fixed point system, update and store the frequency domain block weight on a block basis, and send it to the filtering module for use after converting the adjustment of the frequency domain block weight to block floating point system. The definitions of interfaces in this module are shown in table 5.

TABLE 5

| Definitions | | Bit | |
|---|---|---|---|
| of Interfaces | I/O | width | Illustration |
| det_wk_re | I | 32 | Real part of adjustment of weight |
| det_wk_im | I | 32 | Imaginary part of adjustment of weight |
| det_wk_valid | I | 1 | Valid flag of adjustment of weight |
| blk_det_wk | I | 6 | Block index of adjustment of weight |
| re_weight | I | 1 | Flag signal for starting reading the |
| | | | weight and sending the weight to |
| | | | the filtering module |
| wk_re | O | 16 | Real part of frequency domain weight |
| | | | coefficient |
| wk_im | O | 16 | Imaginary part of frequency domain |
| | | | weight coefficient |
| wk_valid | O | 1 | Valid flags of frequency domain |
| | | | weight coefficient |
| blk_wk | O | 6 | Block index of frequency domain |
| | | | weight coefficient |

Improved the precision of data and reduced quantization error needs to be considered during the storage of frequency domain block weight since the frequency domain block weight(s) of FBLMS algorithm is continuously updated through the recursive formula, and the error will continue to be accumulated. If the accuracy of the data is not high, the error will be very large after many iterations, which will seriously affect the performance of the algorithm, and may cause non convergence or large steady-state error of the algorithm. If the block floating point format is used for storage, the amount of frequency domain block weight adjustment ΔW(k) when the weight is updated and the old frequency domain block weight W(k) before the update are the block floating point system. The order matching shall be performed before summing ΔW(k) and W(k). During the order matching, the data shall be shifted for bit, which will shift the significant bit of the data out and errors occur. Especially when the algorithm enters into the convergence state, the frequency domain block weight fluctuates near the optimal value wₒₚₜ, at this time, the adjustment A W(k)of the frequency domain block weightwill be small, while the old frequency domain block weight W(k) will be large. While matching the order, shifting the ΔW(k) to right by multiple bits is required according to the principle of smaller order to larger order, which will bring large errors and make a large deviation between the frequency domain block weight W(k+1) and the optimal value wₒₚₜ, thus, the algorithm may secede from the convergence state or the steady-state error may increase. If the fixed point format is used for storage, the bit width of the data can be extended to make it have a large dynamic range and ensure that there will be no overflow in the process of coefficient update; and since there is a higher data accuracy, the quantization error of coefficient is small, which has a less impact on the performance of the algorithm. In order to ensure the performance of the algorithm, the weight coefficient should be stored in a fixed point format with large bit width.

The adjustment amount ΔW(k) of the frequency domain block weight is in a block floating point system and should be converted to fixed point system. Before converting the adjustment amount ΔW(k) to fixed point system, the number of bits of the adjustment amountΔW(k) needs to be extended. The extended number of bits is the number of bits when the frequency domain block weight is stored. Assuming that an extended bit width is B, two situations should be considered in the determination of B: on the one hand, when removing the block index of ΔW(k), the mantissa data should be shifted according to the size of the block index, and it should ensure that the shifted data will not overflow with the bit width B. On the other hand, in the recursive process of updating frequency domain block weight, W(k) increases continuously from the initial value of zero until it enters the convergence state and fluctuates up and down near the optimal value. It should ensure that no overflow will occur in the process of coefficient updating with the bit width B. The value of B can be determined by multiple simulations under specific conditions, which is set to 36 in one embodiment of the present disclosure.

It can be seen from the above that bit width of the mantissa data of ΔW(k) is 32 bits, and its decimal point is at the 30th bit, and ΔW(k) needs to be changed into B bit through sign bit extension, and then is shifted according to the size of block index blk det wk to be converted to a fixed point number.

The frequency domain block weight is stored using simple dual ports RAM with a bit width of B and a bit depth of L. When the valid flag det wk valid of the adjustment amount of the frequency domain block weight is 1, the old frequency domain block weights are read out one by one from RAM and added with the corresponding adjustment amount of frequency domain block weight to obtain a new frequency domain block weight and the new frequency domain block weight is written back to the original position in RAM to cover the old value. When updating all positions in RAM is completed, the frequency domain block weight W(k+1) required for the next data filtering is obtained.

When the filtering module reads out the frequency domain block weight for use, the read frequency domain block weights also need to be converted to block floating point system through dynamic truncation. The method of performing dynamic truncation on data is the same as that of the filtering module. While writing the new frequency domain block weight back to RAM, the maximum absolute value of the frequency domain block weight is determined through comparison, and the truncation position m is determined according to the maximum absolute value. When the frequency domain block weight is read out, 16 bits is truncated from the position m. The decimal point of the weight data before the truncation is performed is at the 30th bit, and the block index blk_wk of the truncated weight data is m-30.

In order to verify the effectiveness of the present disclosure, taking the application of FBLMS algorithm in clutter cancellation in external emitter radar system as an example, the algorithm implementation verification platform is constructed by FPGA+MATLAB. Firstly, the simulation conditions are configured, and then data source file is generated in MATLAB, where the data source file includes direct wave data file and target echo data file. The data file is divided into two files, where FBLMS cancellation processing is directly performed on the one file in MATLAB to obtain the cancellation result data file, and the other file is sent to FPGA chip after being subjected to format conversion to perform FBLMS cancellation processing in FPGA and generate the cancellation result data file. The two cancellation result data files are processed in MATLAB to obtain error convergence curves, respectively. The implementation results of the algorithm function are verified by comparison.

XC6VLX550T chip of Virtex-6 series of XILINX company is selected as the hardware platform for algorithm implementation, and its resource utilization ratio is shown in table 6.

TABLE 6

| Slice | FF | BRAM | LUT | DSP48 |
|---|---|---|---|---|
| 2% | 46% | 5% | 4% | 8% |

As shown in FIG. 6, it is a comparison diagram of the error convergence curve of clutter cancellation application of an embodiment of the FPGA implementation device for FBLMS algorithm based on block floating point according to the present disclosure. The first error convergence curve obtained by cancellation process in MATLAB and the second error convergence curve obtained by cancellation process in FPGA approximately coincide, and the difference between the first and second error convergence curves is only about 0.1dB. It verifies the correctness of the FPGA processing result and explains that after the FBLMS algorithm based on block floating point is implemented in FPGA, it can not only complete the clutter cancellation function, but also occupy little hardware resource while ensuring the performance of the algorithm.

The FPGA implementation method for FBLMS algorithm based on block floating point according to the second embodiment of the present disclosure, which is based on the above FPGA implementation device for FBLMS algorithm based on block floating point, includes:

Step S10, blocking, caching and reassembling the input time domain reference signal x(n) according to an overlap-save method, converting blocked, cached and reassembled signal from a fixed point system to a block floating point system and performing fast Fourier transform (FFT) to obtain X(k);

Step S20, multiplying X(k) by a current frequency domain block weight W(k) to a multiplication result, determining the significant bit according to the maximum absolute value in the the multiplication result, and then performing dynamic truncation to obtain the filtered frequency domain reference signal Y(k);

Step S30, performing inverse fast Fourier transform (IFFT) on Y(k) and discarding points to obtain the time domain filter output y(k), caching the target signal d(n) on a block basis and converting the cached target signal d(n) to block floating point system to obtain d(k), and subtracting y(k) from d(k) to obtain the error signal e(k);

Step S40, converting the error signal e(k) to fixed point system, then caching and outputting to obtain output continuously final cancellation result signals e(n).

The frequency domain block weight W(k) is adjusted, calculated and updated synchronously with the error signal e(k) and X(k) by the following steps:

Step X10, inserting zero block in e(k) and then performing FFT to obtain the frequency domain error E(k);

Step X20, calculating a conjugation of X(k) and multiplying by E(k), and then multiplying by the set step factor ,u to obtain an adjustment amount ΔW(k) of the frequency domain block weight;

Step X30, converting ΔW(k) to extended bit width fixed point system and summing it with the current frequency domain block weight W(k) to obtain the updated frequency domain block weight W(k+1); and

Step X40, determining the significant bit during storage of the updated frequency domain block weight W(k+1) when the updated frequency domain block weight W(k+1) is stored, and performing a dynamic truncation on the updated frequency domain block weight W(k+1) when being output and converting it to block floating point system to be used as the frequency domain block weight for a next stage.

Those skilled in the art can clearly understand that for the convenience and simplicity of description, the specific working process and relevant description of the method described above can refer to the corresponding process in the above device embodiment, which will not be repeated here.

It should be noted that the FPGA implementation device and method for FBLMS algorithm based on block floating point provided by the above embodiment only illustrated by divided into the above functional modules. In practical application, the above functions can be allocated by different functional modules according to needs, that is, the modules or steps in the embodiment of this disclosure can be decomposed or combined, for example, the modules of the above embodiment can be combined into one module, and which can also be further divided into multiple sub modules to fulfil all or part of the functions described above. The names of the modules and steps involved in the embodiment of this disclosure are only to distinguish each module or step, and are not regarded as improper restrictions on this disclosure.

The terms “first” and “second” are used to distinguish similar objects, not to describe or express a specific sequence or order.

The term “include” or any other similar term is intended to be nonexclusive so that a process, method, article or equipment/device that includes a series of elements includes not only those elements, but also other elements not explicitly listed, or elements inherent in these processes, methods, articles or equipment/devices.

So far, the technical solution of this disclosure has been described in conjunction with the preferred embodiments shown in the drawings. However, it is easy for those skilled in the art to understand that the protection scope of this disclosure is obviously not limited to these specific embodiments. On the premise of not deviating from the principle of this disclosure, those skilled in the art can make equivalent changes or substitutions to the relevant technical features, and the technical solutions after these changes or substitutions will fall within the protection scope of this disclosure

1. An FPGA implementation device for an FBLMS algorithm based on block floating point, comprising an input caching and converting module, a filtering module, an error calculating and output caching module, a weight adjustment amount calculating module and a weight updating and storing module, in which
the input caching and converting module is suitable for blocking, caching, and reassembling an input time domain reference signal according to an overlap-save method, converting the blocked, cached and reassembled signal from a fixed point system to a block floating point system, and then performing fast Fourier transform (FFT) and caching mantissa, to obtain a frequency domain reference signal with a block floating point system, and outputting the frequency domain reference signal with block floating point system to the filtering module and the weight adjustment amount calculating module;
the filtering module is suitable for performing complex multiplication on the frequency domain reference signal with block floating point system and a frequency domain block weight sent by the weight updating and storing module to obtain a complex multiplication result, determining a significant bit according to a maximum absolute value in the complex multiplication result, and then performing dynamic truncation to obtain a filtered frequency domain reference signal, and sending the filtered frequency domain reference signal to the error calculating and output caching module;
the error calculating and output caching module is configured to perform inverse fast Fourier transform (IFFT) on the filtered frequency domain reference signal; the error calculating and output caching module is further configured to perform ping pong cache on an input target signal and convert the cached target signal to a block floating point system; the error calculating and output caching module is further configured to calculate a difference between the target signal converted to block floating point system and the reference signal on which IFFT is performed to obtain an error signal; and the error calculating and output caching module is further configured to divide the error signal into two same signals, where one of which is sent to the weight adjustment amount calculating module, and the other is converted to fixed point system, and then is subjected to cyclic caching, to obtain output continuously cancellation result signals;
the weight adjustment amount calculating module is configured to obtain an adjustment amount of frequency domain block weight with block floating point system based on the error signal and the frequency domain reference signal with block floating point system; and
the weight updating and storing module is configured to convert the adjustment amount of frequency domain block weight with block floating point system to an extended bit width fixed point system, and then updates and stores the updated frequency domain block weight on a block basis; and the weight updating and storing module is further configured to perform dynamic truncation on the updated frequency domain block weight, and then convert a dynamic truncation result to block floating point system, and send the dynamic truncation result to the filtering module.

2. The device of claim 1, wherein the input caching and converting module comprises a RAM1, a RAM2, a RAM3, a reassembling module, a converting module 1, an FFT module 1 and a RAM4;
the RAM1, RAM2 and RAM3 are configured to divide the input time domain reference signal into data blocks with a length of N by means of cyclic caching;
the reassembling module is configured to reassemble the data blocks with the length of N according to the overlap-save method to obtain an input reference signal with a block length of L point(s); where L=N+M−1 and M is an order of a filter;
the converting module 1 is configured to convert the input reference signal with the block length of L point(s) from fixed point system to block floating point system, and send the converted input reference signal to the FFT module 1;
the FFT module 1 is configured to perform FFT conversion on the data sent by the converting module 1 to obtain a frequency domain reference signal with block floating point system; and
the RAM4 is configured to cache a mantissa of the frequency domain reference signal with block floating point system.

3. The device of claim 2, wherein the blocking, caching and reassemble the input time domain reference signal according to the overlap-save method comprises:
step F10, storing K data in the input time domain reference signal to an end of AM1 successively; where K=M−1 and M is the order of the filter;
step F20, storing a first batch of N data subsequent to the K data to RAM2 successively;
step F30, storing a second batch of N data subsequent to the first batch of N data to RAM3 successively, and taking the K data at the end of RAM1 and N data in RAM2 as an input reference signal with block length of L point(s), where L=K+N;
step F40, storing a third batch of N data subsequent to the second batch of N data to RAM1 successively, and taking the K data at an end of RAM2 and N data in RAM3 as the input reference signal with block length of L point(s);
step F50, storing a fourth batch of N data subsequent to the third batch of N data to RAM2 successively, and taking the K data at an end of RAM3 and N data in RAM1 as the input reference signal with block length of L point(s); and
step F60, turning to step F30 and repeating step F30 to step F60 until all data in the input time domain reference signal is processed.

4. The device of claim 1, wherein the filtering module comprises a complex multiplication module 1, a RAMS and a dynamic truncation module 1 in which,
the complex multiplication module 1 is configured to perform complex multiplication on the frequency domain reference signal with block floating point system and the frequency domain block weight sent by the weight updating and storing module to obtain a complex multiplication result;
the RAMS is configured to cache a mantissa of a data on which the complex multiplication operation has been performed; and
the dynamic truncation module 1 is suitable for determining a data significant bit according to the maximum absolute value in the complex multiplication result, and then performing dynamic truncation to obtain the filtered frequency domain reference signal.

5. The device of claim 4, wherein the determining the data significant bit according to the maximum absolute value in the complex multiplication result, and then performing dynamic truncation comprises:
step G10: obtaining a data of the maximum absolute value in the complex multiplication result;
step G20, detecting from the highest bit of the data of the maximum absolute value, and searching for an earliest bit that is not 0;
step G30, the earliest bit that is not 0 is an earliest significant data bit, and a bit immediately subsequent to the earliest significant data bit is a sign bit; and
step G40, truncating a mantissa of data by taking the sign bit as a start position of truncation, and adjusting a block index to obtain the filtered frequency domain reference signal.

6. The device of claim 1, wherein the error calculating and output caching module comprises an IFFT module 1, a deleting module, a RAM6, a RAM7, a converting module 2, a difference operation module, a converting module 3, a RAMS, a RAMS and a RAM10, in which:
the IFFT module 1 is configured to perform IFFT on the filtered frequency domain reference signal,
the deleting module is configured to delete a firstM−1 data of a data block on which IFFT has been performed to obtain a reference signal with a block length of N point(s) where M is an order of the filter,
the RAM6 and RAM7 are configured to perform ping-pong cache on the input target signal to obtain a target signal with a block length of N point(s),
the converting module 2 is configured to convert the target signal with the block length of N point(s) to block floating point system on a block basis;
the difference operation module is configured to calculate a difference between the target signal converted to block floating point system and the reference signal with block length of N point(s) to obtain an error signal; and divide the error signal into two same signals and send the two same signals to the weight adjustment amount calculating module and the converting module 3, respectively,
the converting module 3 is configured to convert the error signal to fixed point system; and
the RAMS, RAM9 and RAM10 are configured to convert the error signal with fixed point system to output continuously cancellation result signals by means of cyclic caching.

7. The device of claim 1, wherein the weight adjustment amount calculating module comprises a conjugate module, a zero inserting module, an FFT module 2, a complex multiplication module 2, a RAM11, a dynamic truncation module 2, an IFFT module 2, a zero setting module, an FFT transformation module 3 and a product module in which:
the conjugate module is configured to perform conjugation operation on the frequency domain reference signal with block floating point system output from the input caching and converting module,
the zero inserting module is configured to insert M−1 zeros at the front end of the error signal where M is an order of the filter,
the FFT module 2 is configured to perform FFT conversion on the error signal into which zeroes are inserted,
the complex multiplication module 2 is configured to perform complex multiplication on the data on which the conjugation operation is performed and the data on which FFT is performed to obtain a complex multiplication result,
the RAM11 is configured to cache a mantissa of the complex multiplication result,
the dynamic truncation module 2 is configured to determine a data significant bit according to the maximum absolute value in the complex multiplication result of the multiplication module 2, and then perform dynamic truncation to obtain an update amount of the frequency domain block weight,
the IFFT module 2 is configured to perform IFFT on the update amount of the frequency domain block weight,
the zero setting module is configured to set L-M data point(s) at a rear end of the data block on which the IFFT is performed by the IFFT module 2 to 0,
the FFT module 3 is configured to preform FFT on the data output from the zero setting module; and
the product module is configured to perform product operation between the data on which FFT is performed by the FFT transformation module 3 and a set step factor to obtain an adjustment amount of the frequency domain block weight with block floating point system.

8. The device of claim 1, wherein the weight updating and storing module comprises a converting module 4, a summing operation module, a RAM12, a dynamic truncation module 3 and a converting module 5 in which:
the converting module 4 is configured to convert the adjustment amount of the frequency domain block weight with block floating point system output from the weight adjustment amount calculating module to the extended bit width fixed point system;
the summing operation module is configured to sum the adjustment amount of the frequency domain block weight with extended bit width fixed point system and a stored original frequency domain block weight to obtain an updated frequency domain block weight;
the RAM12 is configured to cache the updated frequency domain block weight;
the dynamic truncation module 3 is configured to determine a data significant bit according to the maximum absolute value in the cached updated frequency domain block weight, and then perform dynamic truncation; and
the converting module 5 is configured to convert the data output from the dynamic truncation module 3 to block floating point system to obtain a frequency domain block weight required by the filtering module.

9. An FPGA implementation method for FBLMS algorithm based on block floating point, which is based on the FPGA implementation device for FBLMS algorithm based on block floating point of claim 1, the method comprises:
step S10, blocking, caching and reassembling an input time domain reference signal x(n) according to an overlap-save method, converting blocked, cached and reassembled signal from a fixed point system to a block floating point system and performing fast Fourier transform (FFT) to obtain X(k),
step S20, multiplying X(k) by a current frequency domain block weight W(k) to obtain a multiplication result, determining a significant bit according to a maximum absolute value in the multiplication result, and then performing dynamic truncation to obtain a filtered frequency domain reference signal Y(k),
step S30, performing inverse fast Fourier transform (IFFT) on Y(k) and discarding points to obtain a time domain filter output y(k), caching a target signal d(n) on a block basis and converting the cached target signal d(n) to block floating point system to obtain d(k), and subtracting y(k) from d(k) to obtain an error signal e(k), and
step S40, converting the error signal e(k) to fixed point system, then caching and outputting to obtain a final cancellation result signal e(n) output continuously.

10. The method of claim 9, wherein the frequency domain block weight W(k) is adjusted, calculated and updated synchronously with the error signal e(k) and X(k) by the following steps:
step X10, inserting zero block in e(k) and then performing FFT to obtain the frequency domain error E(k);
step X20, calculating a conjugation of X(k) and multiplying by E(k), and then multiplying by a set step factor ,u to obtain an adjustment amount ΔW(k) of a frequency domain block weight;
step x30, converting ΔW(k) to extended bit width fixed point system and summing the extended ΔW(k) with the current frequency domain block weight W(k) to obtain an updated frequency domain block weight W(k+1);
step X40, determining a significant bit during storage of the updated frequency domain block weight W(k+1) when the updated frequency domain block weight W(k+1) is stored, and performing a dynamic truncation the updated frequency domain block weight W(k+1) when being output to obtain a dynamic truncation result and converting the dynamic truncation result to block floating point system, to be used as a frequency domain block weight for a next stage.
